(19) United States
(12) Patent Application Publication
(10) Pub. No.: US 2011/0148438 A1
(43) Pub. Date: Jun. 23, 2011

(54) SYSTEM AND METHOD FOR DETERMINING A NUMBER OF OBJECTS IN A CAPACITIVE SENSING REGION USING A SHAPE FACTOR

(75) Inventor: Tracy Scott Dattalo, Santa Clara, CA (US)

(73) Assignee: SYNAPTICS INCORPORATED, Santa Clara, CA (US)

(21) Appl. No.: 12/642,467

(22) Filed: Dec. 18, 2009

(51) Int. Cl. G01R 27/26

(52) U.S. Cl. 324/671

(57) ABSTRACT

An input device and method are provided that facilitate improved usability. The input device comprises an array of capacitive sensing electrodes and a processing system. The processing system is configured to receive sensing signals from the capacitive sensing electrodes and generate a plurality of sensing values. The processing system is further configured to calculate a sensing profile from the sensing values, calculate a profile span from the sensing values, and determine a shape factor from the sensing profile and the profile span. Finally, the processing system is configured to determine a number of objects in the sensing region from the determined shape factor. Thus, the sensor device facilitates the determination of the number of objects in the sensing region.

### FIELD OF THE INVENTION

This invention generally relates to electronic devices, and more specifically relates to sensor devices and using sensor devices for producing user interface inputs.

### BACKGROUND OF THE INVENTION

Proximity sensor devices (also commonly called touch sensor devices) are widely used in a variety of electronic systems. A proximity sensor device typically includes a sensing region, often demarked by a surface, in which input objects may be detected. Example input objects include fingers, styli, and the like. The proximity sensor device may utilize one or more sensors based on capacitive, resistive, inductive, optical, acoustic and/or other technology. Further, the proximity sensor device may determine the presence, location and/or motion of a single input object in the sensing region, or of multiple input objects simultaneously in the sensor region.

The proximity sensor device may be used to enable control of an associated electronic system. For example, proximity sensor devices are often used as input devices for larger computing systems, including: notebook computers and desktop computers. Proximity sensor devices are also often used in smaller systems, including: handheld systems such as personal digital assistants (PDAs), remote controls, and communication systems such as wireless telephones and text messaging systems. Increasingly, proximity sensor devices are used in media systems, such as CD, DVD, MP3, video or other media recorders or players. The proximity sensor device may be integral or peripheral to the computing system with which it interacts.

In the past, some proximity sensor devices have had limited ability to detect and distinguish between one or more objects in the sensing region. For example, some capacitive sensor devices may detect a change in capacitance resulting from an object or objects being in the sensing region but may not be able to reliably determine if the change was caused by one object or multiple objects in the sensing region. This limits the flexibility of the proximity sensor device in providing different types of user interface actions in response to different numbers of objects or gestures with different numbers of objects.

This limitation is prevalent in some capacitive sensors generally referred to as “profile sensors”. Profile sensors use arrangements of capacitive electrodes to generate signals in response one or more objects in the sensing region. Taken together, these signals comprise a profile that may be analyzed determine the presence and location of objects in the sensing region. In a typical multi-dimensional sensor, capacitance profiles are generated and analyzed for each of multiple coordinate directions. For example, an “X profile” may be generated from capacitive electrodes arranged along the X direction, and a “Y profile” may be generated for electrodes arranged in the Y direction. These two profiles are then analyzed to determine the position of any object in the sensing region.

Because of ambiguity in the capacitive response, it may be difficult for the proximity sensor to reliably determine if the capacitive profile is the result of one or more objects in the sensing region. This can limit the ability of the proximity sensor to distinguish between one or more objects and thus to provide different interface actions in response to different numbers of objects.

Thus, what is needed are improved techniques for quickly and reliably distinguishing between one or more objects in a sensing region of a proximity sensor device, and in particular, object(s) in the sensing region of capacitive profile sensors. Other desirable features and characteristics will become apparent from the subsequent detailed description and the appended claims, taken in conjunction with the accompanying drawings and the foregoing technical field and background.

### BRIEF SUMMARY OF THE INVENTION

The embodiments of the present invention provide a device and method that facilitates improved sensor device usability. Specifically, the device and method provide improved device usability by facilitating the reliable determination of the number objects in a sensing region of a capacitive sensors. For example, the device and method may determine if one object or multiple objects are in the sensing region. The determination of the number of objects in the sensing region may be used to facilitate different user interface actions in response to different numbers of objects, and thus can improve sensor device usability.

In one embodiment, a sensor device comprises an array of capacitive sensing electrodes and a processing system coupled to the electrodes. The capacitive sensing electrodes are configured to generate sensing signals that are indicative of objects in a sensing region. The processing system is configured to receive sensing signals from the capacitive sensing electrodes and generate a plurality of sensing values. The processing system is further configured to calculate a sensing profile from the sensing values, calculate a profile span from the sensing values, and determine a shape factor from the sensing profile and the profile span. Finally, the processing system is configured to determine a number of objects in the sensing region from the determined shape factor. Thus, the sensor device facilitates the determination of the number of objects in the sensing region, and may thus be used to facilitate different user interface actions in response to different numbers of objects.

In another embodiment, a method is provided for determining a number of objects in a sensing region of a capacitive sensor with a first array of capacitive sensing electrodes. In this embodiment, the method comprises the steps of receiving sensing signals from the first array of capacitive sensing electrodes and generating sensing values from the sensing signals. The method further comprises the steps of calculating a sensing profile from the sensing values, calculating a profile span from the second set of sensing values, determining a shape factor from the sensing profile and the profile span, and determining a number of objects in the sensing region from the shape factor. Thus, the method facilitates the determination of the number of objects in the sensing region, and may thus be used to facilitate different user interface actions in response to different numbers of objects.

### BRIEF DESCRIPTION OF DRAWINGS

The preferred exemplary embodiment of the present invention will hereinafter be described in conjunction with the appended drawings, where like designations denote like elements, and wherein:

FIG. 1 is a block diagram of an exemplary system that includes an input device in accordance with an embodiment of the invention;

FIG. 2 is a schematic view of an exemplary electrode array in accordance with an embodiment of the invention;

FIG. 3 is a top view an input device with one object in the sensing region in accordance with an embodiment of the invention;

FIG. 4 is a side view an input device with one object in the sensing region in accordance with an embodiment of the invention;

FIGS. 5 and 6 are graphs of sensing value magnitudes for one object in the sensing region in accordance with an embodiment of the invention;

FIG. 7 is a top view an input device with multiple objects in the sensing region in accordance with an embodiment of the invention;

FIG. 8 is a side view an input device with multiple objects in the sensing region in accordance with an embodiment of the invention;

FIGS. 9 and 10 are graphs of sensing value magnitudes for multiple objects in the sensing region in accordance with an embodiment of the invention;

FIG. 11 is a method for determining a number of objects in a sensing region in accordance with an embodiment of the invention;

FIG. 12 is a graph of baseline values generated during a time when no objects are in the sensing region in accordance with an embodiment of the invention; and

FIGS. 13 and 14 are graphs of exemplary sensing values generated during a time when objects are in the sensing region in accordance with an embodiment of the invention.

### DETAILED DESCRIPTION OF THE INVENTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

The embodiments of the present invention provide a device and method that facilitates improved sensor device usability. Specifically, the device and method provide improved device usability by facilitating the reliable determination of the number objects in a sensing region of a capacitive sensors. For example, the device and method may determine if one object or multiple objects are in the sensing region. The determination of the number of objects in the sensing region may be used to facilitate different user interface actions in response to different numbers of objects, and thus may improve sensor device usability.

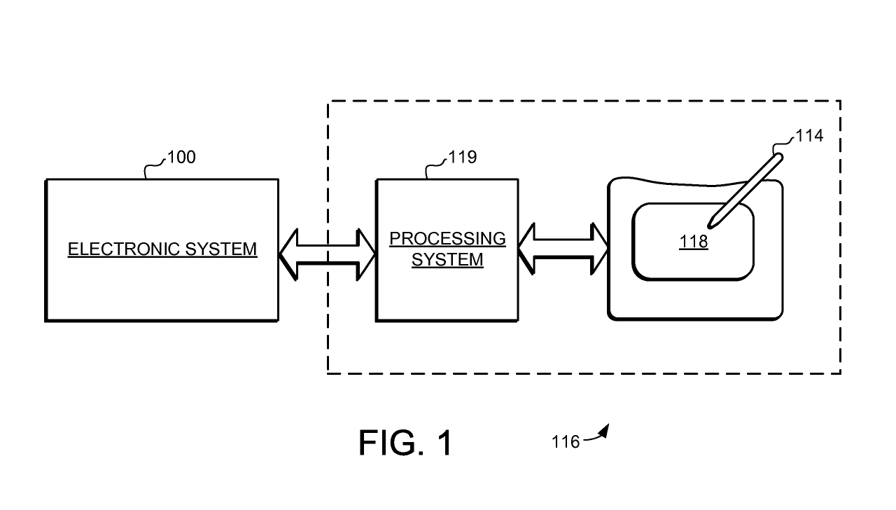

Turning now to the drawing figures, FIG. 1 is a block diagram of an exemplary electronic system 100 that operates with an input device 116. As will be discussed in greater detail below, the input device 116 may be implemented to function as an interface for the electronic system 100. The input device 116 has a sensing region 118 and is implemented with a processing system 119. Not shown in FIG. 1 is an array of sensing electrodes that are adapted to capacitively sense objects in the sensing region 118.

The input device 116 is adapted to provide user interface functionality by facilitating data entry responsive to sensed objects. Specifically, the processing system 119 is configured to determine positional information for multiple objects sensed by a sensor in the sensing region 118. This positional information may then be used by the system 100 to provide a wide range of user interface functionality.

The input device 116 is sensitive to input by one or more input objects (e.g. fingers, styli, etc.), such as the position of an input object 114 within the sensing region 118. “Sensing region” as used herein is intended to broadly encompass any space above, around, in and/or near the input device in which sensor(s) of the input device is able to detect user input. In a conventional embodiment, the sensing region of an input device extends from a surface of the sensor of the input device in one or more directions into space until signal-to-noise ratios prevent sufficiently accurate object detection. The distance to which this sensing region extends in a particular direction may be on the order of less than a millimeter, millimeters, centimeters, or more, and may vary significantly with the type of sensing technology used and the accuracy desired. Thus, embodiments may require contact with the surface, either with or without applied pressure, while others do not. Accordingly, the sizes, shapes, and locations of particular sensing regions may vary widely from embodiment to embodiment.

Sensing regions with rectangular two-dimensional projected shape are common, and many other shapes are possible. For example, depending on the design of the sensor array and surrounding circuitry, shielding from any input objects, and the like, sensing regions may be made to have two-dimensional projections of other shapes. Similar approaches may be used to define the three-dimensional shape of the sensing region. For example, any combination of sensor design, shielding, signal manipulation, and the like may effectively define a sensing region 118 that extends some distance into or out of the page in FIG. 1.

In operation, the input device 116 suitably detects one or more input objects (e.g. the input object 114) within the sensing region 118. The input device 116 thus includes a sensor (not shown) that utilizes any combination sensor components and sensing technologies to implement one or more sensing regions (e.g. sensing region 118) and detect user input such as presences of object(s). Input devices may include any number of structures, including one or more capacitive sensor electrodes, one or more other electrodes, or other structures adapted to detect object presence. Devices that use capacitive electrodes for sensing are advantageous to ones requiring moving mechanical structures (e.g. mechanical switches) as they may have a substantially longer usable life.

For example, sensor(s) of the input device 116 may use arrays or other patterns of capacitive sensor electrodes to support any number of sensing regions 118. Examples of the types of technologies that may be used to implement the various embodiments of the invention may be found in U.S. Pat. Nos. 5,543,591, 5,648,642, 5,815,091, 5,841,078, and 6,249,234.

In some capacitive implementations of input devices, a voltage is applied to create an electric field across a sensing surface. These capacitive input devices detect the position of an object by detecting changes in capacitance caused by the changes in the electric field due to the object. The sensor may detect changes in voltage, current, or the like.

As another example, some capacitive implementations utilize transcapacitive sensing methods based on the capacitive coupling between sensor electrodes. Transcapacitive sensing methods are sometimes also referred to as “mutual capacitance sensing methods.” In one embodiment, a transcapacitive sensing method operates by detecting the electric field coupling one or more transmitting electrodes with one or more receiving electrodes. Proximate objects may cause changes in the electric field, and produce detectable changes in the transcapacitive coupling. Sensor electrodes may transmit as well as receive, either simultaneously or in a time multiplexed manner. Sensor electrodes that transmit are sometimes referred to as the “transmitting sensor electrodes,” “driving sensor electrodes,” “transmitters,” or “drivers”—at least for the duration when they are transmitting. Other names may also be used, including contractions or combinations of the earlier names (e.g. “driving electrodes” and “driver electrodes.” Sensor electrodes that receive are sometimes referred to as “receiving sensor electrodes,” “receiver electrodes,” or “receivers”—at least for the duration when they are receiving. Similarly, other names may also be used, including contractions or combinations of the earlier names. In one embodiment, a transmitting sensor electrode is modulated relative to a system ground to facilitate transmission. In another embodiment, a receiving sensor electrode is not modulated relative to system ground to facilitate receipt.

In FIG. 1, the processing system (or “processor”) 119 is coupled to the input device 116 and the electronic system 100. Processing systems such as the processing system 119 may perform a variety of processes on the signals received from the sensor(s) and force sensors of the input device 116. For example, processing systems may select or couple individual sensor electrodes, detect presence/proximity, calculate position or motion information, or interpret object motion as gestures.

The processing system 119 may provide electrical or electronic indicia based on positional information and force information of input objects (e.g. input object 114) to the electronic system 100. In some embodiments, input devices use associated processing systems to provide electronic indicia of positional information and force information to electronic systems, and the electronic systems process the indicia to act on inputs from users. One example system response is moving a cursor or other object on a display, and the indicia may be processed for any other purpose. In such embodiments, a processing system may report positional and force information to the electronic system constantly, when a threshold is reached, in response criterion such as an identified stroke of object motion, or based on any number and variety of criteria. In some other embodiments, processing systems may directly process the indicia to accept inputs from the user, and cause changes on displays or some other actions without interacting with any external processors.

In this specification, the term “processing system” is defined to include one or more processing elements that are adapted to perform the recited operations. Thus, a processing system (e.g. the processing system 119) may comprise all or part of one or more integrated circuits, firmware code, and/or software code that receive electrical signals from the sensor and communicate with its associated electronic system (e.g. the electronic system 100). In some embodiments, all processing elements that comprise a processing system are located together, in or near an associated input device. In other embodiments, the elements of a processing system may be physically separated, with some elements close to an associated input device, and some elements elsewhere (such as near other circuitry for the electronic system). In this latter embodiment, minimal processing may be performed by the processing system elements near the input device, and the majority of the processing may be performed by the elements elsewhere, or vice versa.

Furthermore, a processing system (e.g. the processing system 119) may be physically separate from the part of the electronic system (e.g. the electronic system 100) that it communicates with, or the processing system may be implemented integrally with that part of the electronic system. For example, a processing system may reside at least partially on one or more integrated circuits designed to perform other functions for the electronic system aside from implementing the input device.

In some embodiments, the input device is implemented with other input functionality in addition to any sensing regions. For example, the input device 116 of FIG. 1 is implemented with buttons or other input devices near the sensing region 118. The buttons may be used to facilitate selection of items using the proximity sensor device, to provide redundant functionality to the sensing region, or to provide some other functionality or non-functional aesthetic effect. Buttons form just one example of how additional input functionality may be added to the input device 116. In other implementations, input devices such as the input device 116 may include alternate or additional input devices, such as physical or virtual switches, or additional sensing regions. Conversely, in various embodiments, the input device may be implemented with only sensing region input functionality.

Likewise, any positional information determined a processing system may be any suitable indicia of object presence. For example, processing systems may be implemented to determine “one-dimensional” positional information as a scalar (e.g. position or motion along a sensing region). Processing systems may also be implemented to determine multi-dimensional positional information as a combination of values (e.g. two-dimensional horizontal/vertical axes, three-dimensional horizontal/vertical/depth axes, angular/radial axes, or any other combination of axes that span multiple dimensions), and the like. Processing systems may also be implemented to determine information about time or history.

Furthermore, the term “positional information” as used herein is intended to broadly encompass absolute and relative position-type information, and also other types of spatial-domain information such as velocity, acceleration, and the like, including measurement of motion in one or more directions. Various forms of positional information may also include time history components, as in the case of gesture recognition and the like. As will be described in greater detail below, positional information from the processing systems may be used to facilitate a full range of interface inputs, including use of the proximity sensor device as a pointing device for selection, cursor control, scrolling, and other functions.

In some embodiments, an input device such as the input device 116 is adapted as part of a touch screen interface. Specifically, a display screen is overlapped by at least a portion of a sensing region of the input device, such as the sensing region 118. Together, the input device and the display screen provide a touch screen for interfacing with an associated electronic system. The display screen may be any type of electronic display capable of displaying a visual interface to a user, and may include any type of LED (including organic LED (OLED)), CRT, LCD, plasma, EL or other display technology. When so implemented, the input devices may be used to activate functions on the electronic systems. In some embodiments, touch screen implementations allow users to select functions by placing one or more objects in the sensing region proximate an icon or other user interface element indicative of the functions. The input devices may be used to facilitate other user interface interactions, such as scrolling, panning, menu navigation, cursor control, parameter adjustments, and the like. The input devices and display screens of touch screen implementations may share physical elements extensively. For example, some display and sensing technologies may utilize some of the same electrical components for displaying and sensing.

It should be understood that while many embodiments of the invention are to be described herein the context of a fully functioning apparatus, the mechanisms of the present invention are capable of being distributed as a program product in a variety of forms. For example, the mechanisms of the present invention may be implemented and distributed as a sensor program on computer-readable media. Additionally, the embodiments of the present invention apply equally regardless of the particular type of computer-readable medium used to carry out the distribution. Examples of computer-readable media include various discs, memory sticks, memory cards, memory modules, and the like. Computer-readable media may be based on flash, optical, magnetic, holographic, or any other storage technology.

As noted above, the input device 116 is adapted to provide user interface functionality by facilitating data entry responsive to sensed proximate objects and the force applied by such objects. Specifically, the input device 116 provides improved device usability by facilitating the reliable determination of the number objects in the sensing region 118. For example, the input device 116 may determine if one object or multiple objects are in the sensing region 118. The determination of the number of objects in the sensing region 118 may be used in determining positional information for the one or multiple objects, and further may be used to provide different user interface actions in response to different numbers of objects, and thus can improve sensor device usability.

In a typical embodiment, the input device 116 comprises an array of capacitive sensing electrodes and a processing system 119 coupled to the electrodes. The capacitive sensing electrodes are configured to generate sensing signals that are indicative of objects in the sensing region 118. The processing system 119 receives sensing signals from the capacitive sensing electrodes and generates a plurality of sensing values.

From those sensing values, the processing system 119 can determine positional information for objects in the sensing region. And in accordance with the embodiments of the invention, the processing system 119 is configured to determine if one or more objects is in the sensing region 118, and may thus distinguish between situations where one object is in the sensing region 118 and situations where two objects are in the sensing region 118. To facilitate this determination, the processing system 119 is configured to calculate a sensing profile from the sensing values and calculate a profile span from the sensing values. Furthermore, the processing system 119 is configured to determine a shape factor from the sensing profile and the profile span. Finally, the processing system 119 is configured to determine a number of objects in the sensing region 118 from the determined shape factor. Thus, the processing system 119 facilitates the determination of the number of objects in the sensing region 118, and may thus be used to facilitate different user interface actions in response to different numbers of objects.

As noted above, the input device 116 may be implemented with a variety of different types and arrangements of capacitive sensing electrodes. To name several examples, the capacitive sensing device may be implemented with electrode arrays that are formed on multiple substrate layers, typically with the electrodes for sensing in one direction (e.g., the “X” direction) formed on a first layer, while the electrodes for sensing in a second direction (e.g., the “Y” direction are formed on a second layer. In other embodiments, the electrodes for both the X and Y sensing may be formed on the same layer. In yet other embodiments, the electrodes may be arranged for sensing in only one direction, e.g., in either the X or the Y direction. In still another embodiment, the electrodes may be arranged to provide positional information in polar coordinates, such as “r” and “θ” as one example. In these embodiments the electrodes themselves are commonly arranged in a circle or other looped shape to provide “θ”, with the shapes of individual electrodes used to provide “r”.

Also, a variety of different electrode shapes may be used, including electrodes shaped as thin lines, rectangles, diamonds, wedge, etc. Finally, a variety of conductive materials and fabrication techniques may be used to form the electrodes. As one example, the electrodes are formed by the deposition and etching of conductive ink on a substrate.

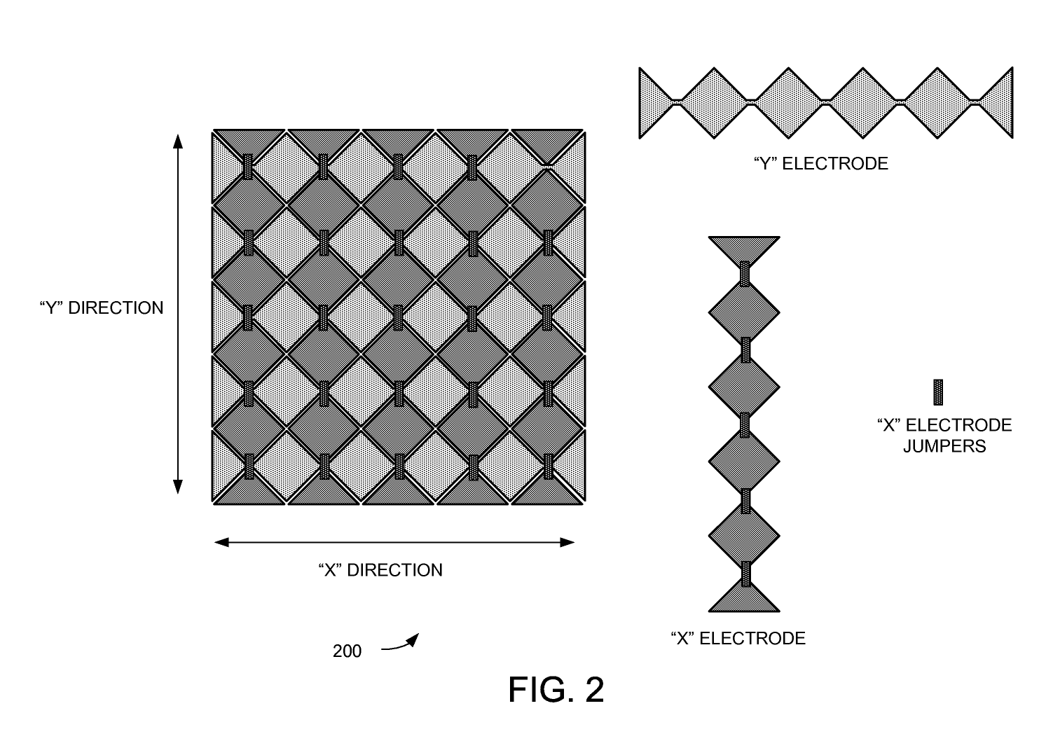

Turning now to FIG. 2, one example of a capacitive array of sensing electrodes 200 is illustrated. These are examples of sensing electrodes that are typically arranged to be “under” or on the opposite side of the surface that is to be “touched” by a user of the sensing device. In this example, the electrodes are configured to sense object position and/or motion in the X direction are formed on the same layer with electrodes configured to sense object position and/or motion in the Y direction. These electrodes are formed with “diamond” shapes that are connected together in a string to form individual X and Y electrodes. It should be noted that while the diamonds of the X and Y electrodes are formed on the same substrate layer, a typical implementation will use “jumpers” formed above, on a second layer, to connect one string of diamonds together. So coupled together, each string of jumper connected diamonds comprises one X or one Y electrode.

In the example of FIG. 2, electrode jumpers for X electrodes are illustrated. Specifically, these jumpers connect one vertical string of the diamonds to form one X electrode. The corresponding connections between diamonds in the Y electrode are formed on the same layer and with the diamonds themselves. Such a connection is illustrated in the upper corner of electrodes 200, where one jumper is omitted to show the connection of the underlying Y diamonds.

Again, it should be emphasized that the sensing electrodes 200 are just one example of the type of electrodes that may be used to implement the embodiments of the invention. For example, some embodiments may include more or less numbers of electrodes. In other examples, the electrodes may be formed on multiple layers. In yet other examples, the electrodes may be implemented with an array of electrodes that have multiple rows and columns of discrete electrodes.

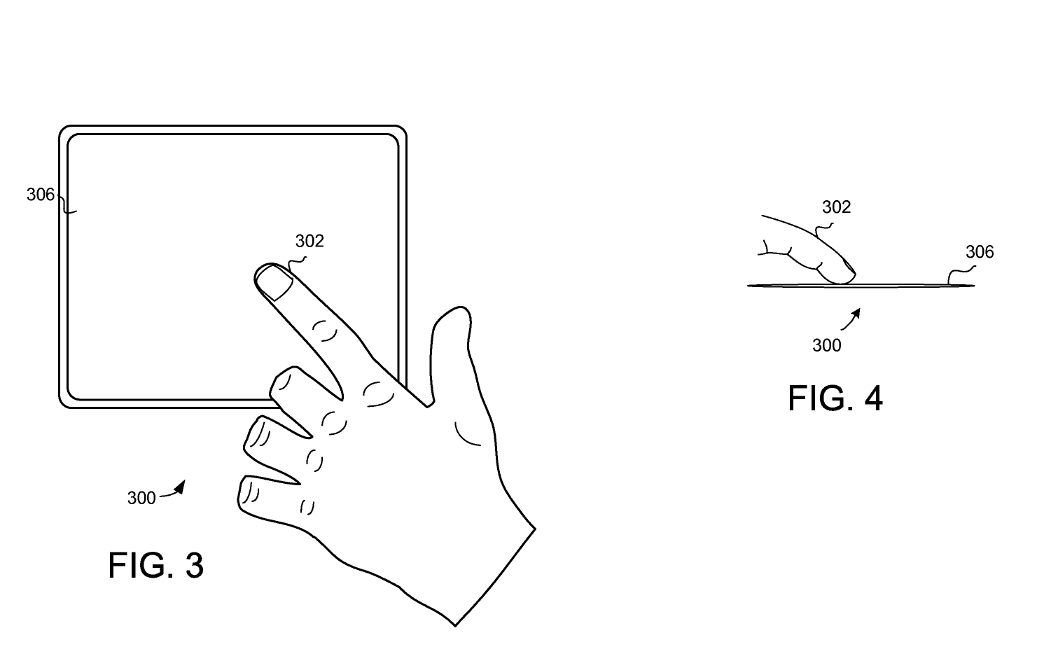

Turning now to FIGS. 3 and 4, examples of an object in a sensing region are illustrated. Specifically, FIGS. 3 and 4 show top and side views of an exemplary input device 300. In the illustrated example, user's finger 302 provides input to the device 300. Specifically, the input device 300 is configured to determine the position of the finger 302 within the sensing region 306 using a sensor. For example, the input device 300 may be implemented using a plurality of electrodes configured to capacitively detect objects such as the finger 306, and a processor configured to determine the position of the fingers from the capacitive detection.

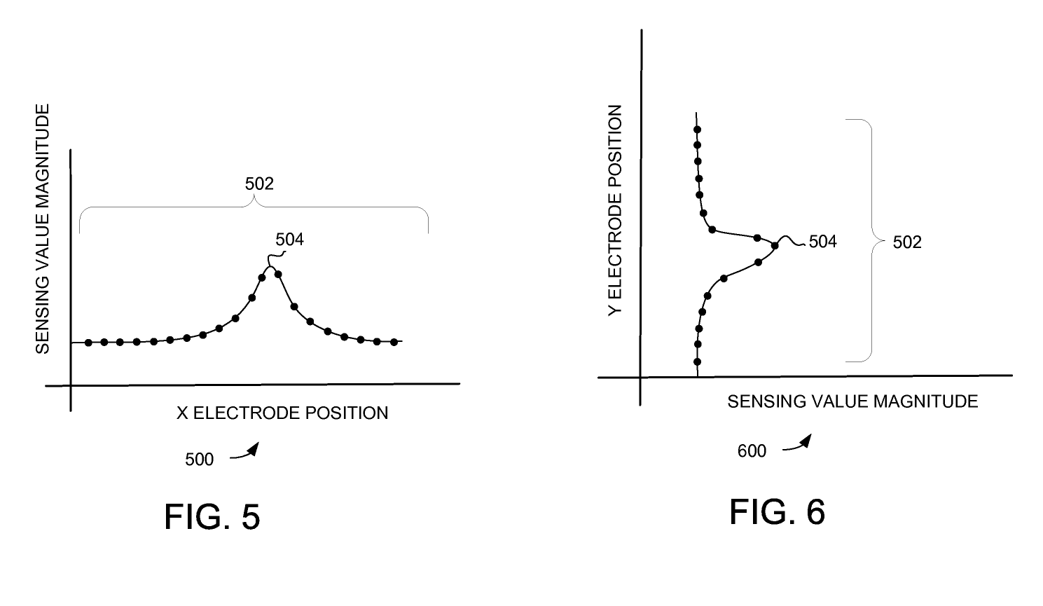

Turning now to FIGS. 5 and 6, graphs 500 and 600 illustrate exemplary sensing values 502 generated from X and Y electrodes in response to the user's finger 302 being in the sensing region 306. In these figures, each sensing value 502 is represented as a dot, and with the magnitude of the sensing value plotted against the position of the corresponding X electrode (FIG. 5) or Y electrode (FIG. 6). As illustrated in FIGS. 5 and 6, the magnitude of the sensing values are indicative of the location of the finger 302 and thus may be used to determine the X and Y coordinates of the finger 302 position. Specifically, when analyzed, the sensing values 502 define a curve, the extrema 504 of which may be determined as used to determine the position of an object (e.g., finger 302) in the sensing region.

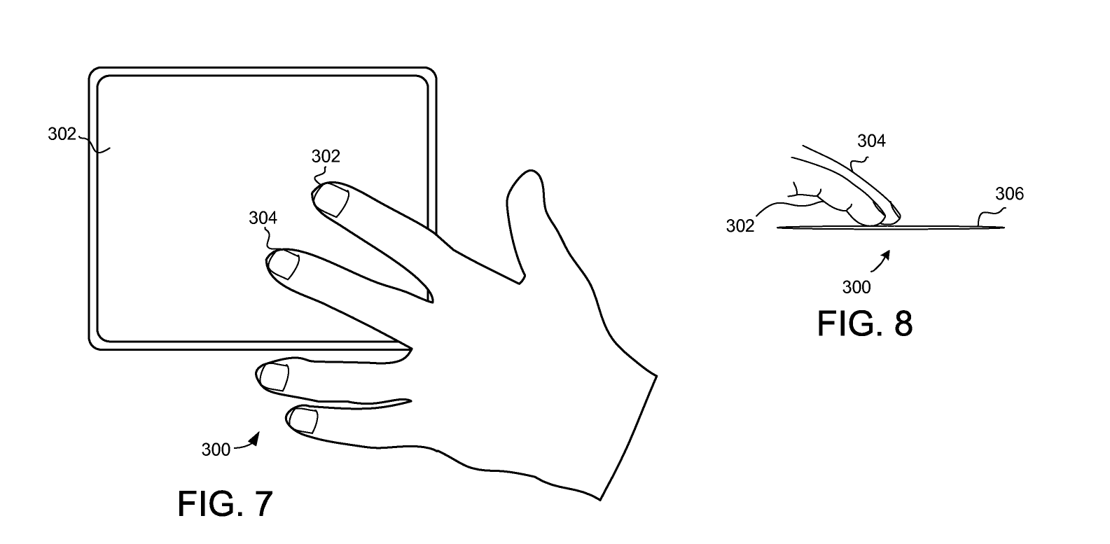

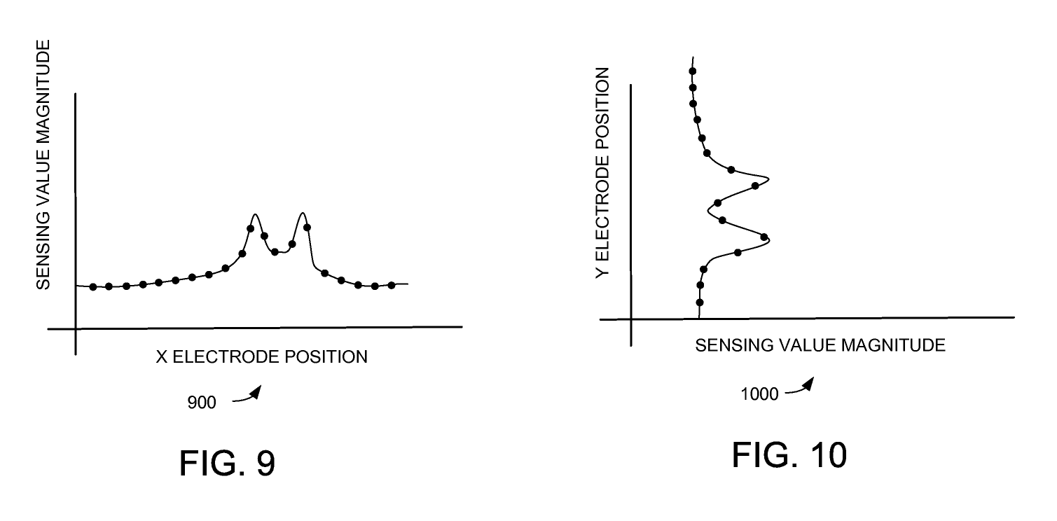

Turning now to FIGS. 7 and 8, second examples of objects in a sensing region are illustrated. Again, FIGS. 7 and 8 show top and side views of an exemplary input device 300. In the illustrated example, user's fingers 302 and 304 provide input to the device 300. Turning now to FIGS. 9 and 10, graphs 900 and 1000 illustrate exemplary sensing values generated from X and Y electrodes in response to the user's fingers 302 and 304 being in the sensing region 306. As illustrated in FIGS. 9 and 10, the magnitude of the sensing values are indicative of the location of the fingers 302 and 304 and thus may be used to determine the X and Y coordinates of the position of fingers 302 and 304.

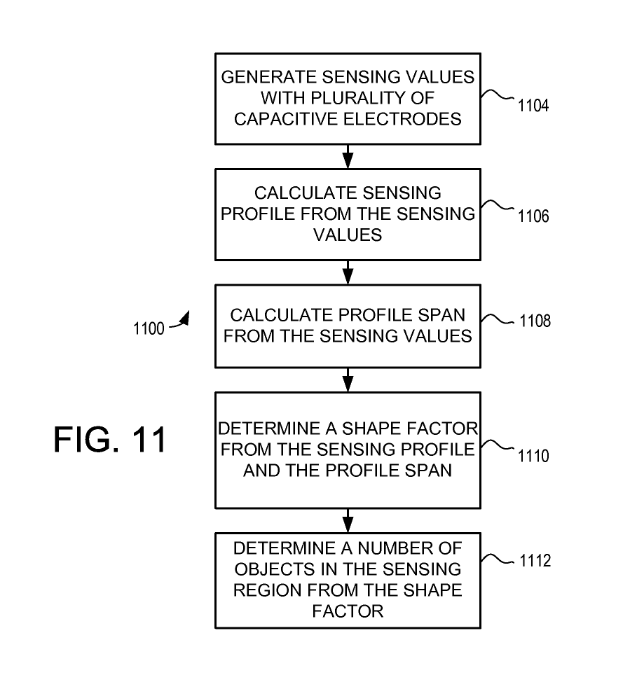

Turning now to FIG. 11, a method 1100 for determining the number of objects in a sensing region is illustrated. In general, the method 1100 receives sensing signals from an array of capacitive sensing electrodes, generates a sensing profile, a profile span, a shape factor, and determines the number of objects in the sensing region from the shape factor. Thus, the method 1100 facilitates the determination of the number of objects in the sensing region, and may thus be used to facilitate different user interface actions in response to different numbers of objects.

The first step 1104 is to generate sensing values with a plurality of capacitive electrodes. As noted above, a variety of different technologies may be used in implementing the input device, and these various implementations may generate signals indicative of object presence in a variety of formats. As one example, the input device may generate signals that correlate to the magnitude of a measured capacitance associated with each electrode. These signals may be based upon measures of absolute capacitance, transcapacitance, or some combination thereof. Furthermore, these signals may then be sampled, amplified, filtered, or otherwise conditioned as desirable to generate sensing values corresponding to the electrodes in the input device.

It should be noted that during operation of a sensor input device, sensing signals are being continuously generated by the input device. Thus, some of these sensing signals may be generated when no objects are within the sensing region. These sensing signals may be used to determine baseline values from which other sensing signals measured.

In such an embodiment, the baseline values may serve as a reference point for measuring changes in the sensing signals that occur over time. Thus, the generating of sensing values in step 1104 may include this determination of baseline values and the subtraction of the baseline values to determine the sensing values. In this case, the sensing values may be considered to be delta values, i.e., the change in sensing values over time compared to baseline values.

In a typical implementation, the input device may be configured to periodically generate new baseline values at a time when it can be determined that no objects are in the sensing region. Once so generated, the baseline values may then be used as a reference for repeated future calculations of the sensing values. It should be noted that the calculation of the baseline values may occur at various times. For example, once per second or once per minute, or every time the device is powered on or awakened from a “sleep” mode. In a typical implementation, the processing system may be configured to recognize when no objects are in the sensing region and then use those identified times to calculate the baseline values.

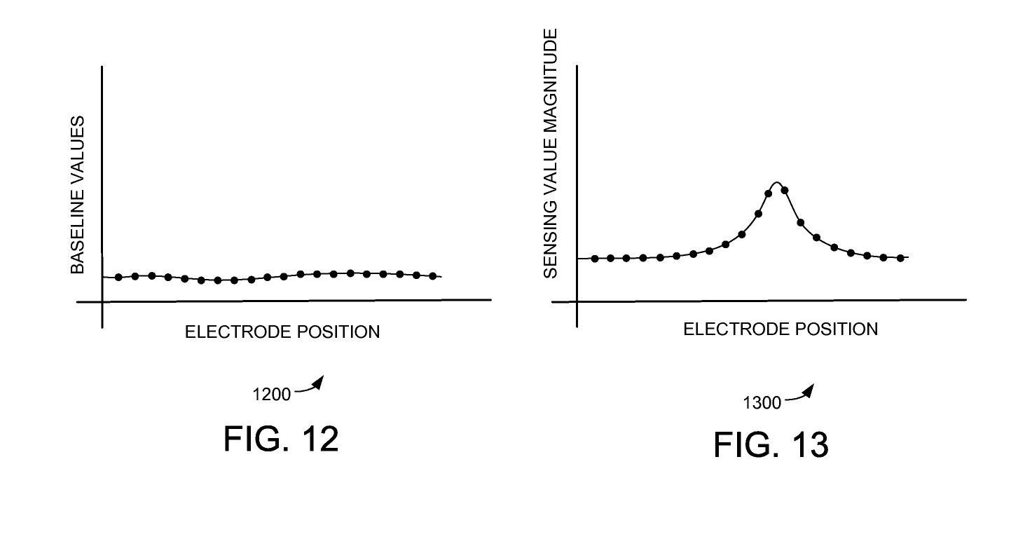

Turning briefly to FIG. 12, a graph 1200 illustrates an exemplary plurality of baseline values generated during a time when no objects are in the sensing region. Although no objects are in the sensing region, background variations in capacitance and signal noise may provide some amount of capacitance measured at each electrode.

Returning to FIG. 11, the next step 1106 is to calculate a sensing profile from the sensing values. In general, a sensing profile is an approximation of the arc length of the sensing values. Specifically, the sensing profile is such an approximation generated from a set of sensing values that correspond to a time when one or more objects may be in the sensing region.

A variety of different techniques may be used to calculate the sensing profile. As noted above, the sensing profile is an approximation of the arc length of the set of sensing values. However, it should be noted that as the sensing values are discrete values generated from electrodes and that there is no actual physical arc for which the length is calculated. Instead, the sensing profile may be described as an approximation of what such an arc length would be for a line drawn through the sensing values, and thus providing a continuous representation of the sensing values. The sensing profile thus estimates the total change in sensing values over the array of electrodes. Different calculation techniques may provide various different estimations of the arc length for the sensing values, such as “one's norm” and “two's norm” techniques for approximating arc length.

As one example, the sensing profile arc length may be determined by calculating difference values for sensing values corresponding to adjacent capacitive sensing electrodes and summing the difference values. As one specific example of such a technique, a sum of absolute differences (SOAD) may be calculated and used to generate the sensing profile. Specifically, a SOAD can be calculated as:

$$SOAD = {\sum }_{i = 2}^{n} \vert {S}_{i} - {S}_{i - 1} \vert . \qquad Equation 1$$

where Sᵢ is the magnitude of the sensing value corresponding the i electrode, Sᵢ₋₁ is the magnitude of the i−1 electrode. Thus, in Equation 1, the SOAD is a summation of the difference in magnitudes between the sensing values corresponding to all the adjacent electrodes. So calculated, the SOAD provides an approximation of the imaginary arc length of the sensing values.

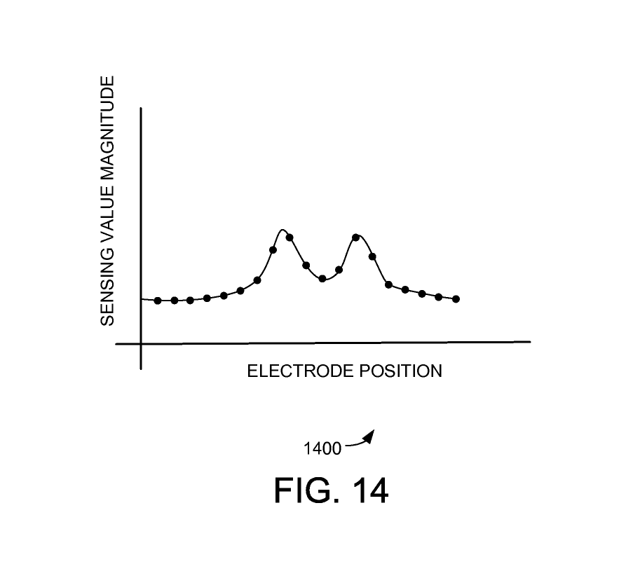

Turning briefly to FIGS. 13 and 14, graphs 1300 and 1400 illustrate exemplary pluralities of sensing values generated during a time when objects are in the sensing region. Specifically, FIG. 13 shows a plurality of sensing values generated when one object (e.g. finger 302) is in the sensing region, and FIG. 14 shows a plurality of sensing values generated when more than one objects (e.g., fingers 302 and 304) are in the sensing region. According to step 1106, the sensing profile of such sensing values may be calculated. For example, the sensing profile may be calculated by calculating the SOAD defined in Equation 1 for a second set of sensing values generated when one or more objects are in the sensing region. Such a calculation would generate an approximation of the arc length of the sensing values illustrated in FIGS. 13 and 14, and would thus provide a sensing profile that can be used to determine the number of objects in the sensing region.

Returning to FIG. 11, the next step 1108 is to calculate a profile span from the second set of sensing values. In step 1108, the profile span is an approximation of the difference in amplitude of the second set of sensing values. For example, the profile span may be calculated by determining a difference between a maximum sensing value and a minimum sensing value from the second set of the sensing values. Specifically, the profile span can be defined as:

SPAN=maxSᵢ−minSᵢ Equation 2.

where max Sᵢ is the maximum sensing value in the second set of sensing values, and min Sᵢ is the minimum sensing value in the second set of sensing values. So calculated, the profile span provides an approximation of the difference in amplitude of the second set of sensing values. Again, it should be noted that Equation 2 is just one example of how a profile span that approximates the difference in amplitude of the second set of sensing values may be calculated.

The next step 1110 is to determine a shape factor from the sensing profile and the profile span. In general, the shape factor is a combination of the sensing profile and the profile span designed to extract features that are indicative of the number of objects in the sensing region. Thus, the shape factor provides an indication of the number of objects in the sensing region and may be used to distinguish between one or more objects in the sensing region. A variety of different techniques may be used to generate the shape factor. As one example, the shape factor may be generated from a linear combination of the sensing profile and the profile span.

As one specific example, the shape factor may be generated by subtracting twice the profile span from the sensing profile. Such a shape factor has been found to be indicative of one or multiple objects in the sensing region.

The next step 1112 is to determine a number of objects in the sensing region from the shape factor. It should first be noted that this step may involve the determination of the actual count of objects in the sensing region (e.g., 1, 2, 3, etc.), or it may more simply involve the determination that one or more objects are in the sensing region.

A variety of techniques may be used to determine the number of objects in the sensing region from the shape factor. As one example, the calculated shape factor may be compared to one or more threshold values. Each threshold may serve to identify a count of objects in the sensing region.

For example, if the shape factor is beyond a first threshold value, then one object in the sensing region may be indicated. Likewise, if the shape factor is beyond a second threshold value, two objects in the sensing region may be indicated. Again, this is just one example of how the shape factor may be used to determine the number of objects in the sensing region.

It should be noted that while the above examples determine a number of objects in the sensing region from sensing values generated by one set of electrodes, the same determination may be made from sensing values generated by other electrodes. For example, in systems that include both X and Y electrodes, both the X and the Y electrodes may provide sensing values that are analyzed to determine the number of objects in the sensing region. The determined number of objects from the second array of electrodes may serve as an independent indication of one or more objects in the sensing region or may be used to confirm the indication made with other electrodes.

Once the number of objects has been determined, it may be used for facilitating different user interface actions in response to different numbers of objects, and thus may improve sensor device usability. For example, the determination that multiple fingers are in a sensing region may be used to initiate gestures such as enhanced scrolling, selecting, etc.

Two specific examples of this technique will now be provided. In these examples, sensing values as illustrated in FIGS. 13 and 14 are calculated. Each set of sensing values has 20 values, each corresponding to one or more electrodes. The sensing values illustrated in FIG. 13 may have exemplary values of {0, 0, 0, 0, 0, 0, 1, 5, 10, 20, 40, 51, 29, 20, 10, 5, 1, 0, 0}. Likewise, the sensing values illustrated in FIG. 14 may have exemplary values of {0, 0, 0, 0, 0, 5, 10, 38, 40, 25, 15, 20, 40, 30, 10, 9, 5, 0, 0}. It should be noted that these values may be calculated as delta values, i.e., the difference from previously calculated baseline values. Furthermore, these values may be filtered and/or scaled as desirable.

Using the examples described above, the sensing profile for these values may be calculated using Equation 1. In that example, the calculated SOAD is an approximation of the arc length of the values and thus may be used as a sensing profile. The exemplary sensing values for FIG. 13, when applied to Equation 1, generate a SOAD value of 102. Likewise, the exemplary sensing values for FIG. 14, when applied to Equation 1, generate a SOAD value of 130.

The profile span on the sensing values may then be calculated using Equation 2. In that example, the calculated SPAN is an approximation of the difference in amplitude within the second set of sensing values. The exemplary sensing values for FIG. 13, when applied to Equation 2, generate a SPAN value of 51. Likewise, the exemplary sensing values for FIG. 14, when applied to Equation 2, generate a SPAN value of 40.

A shape factor may be then generated from a linear combination of the profile span and the sensing profile. For example, a shape factor may then be generated by subtracting twice the profile span from the sensing profile. In these examples, the shape factor for the sensing values of FIG. 13 would be 102−2(51)=0, while the shape factor for the sensing values of FIG. 14 would be 130−2(40)=50. As can be seen, the shape factor for the sensing values corresponding to one object (e.g., FIG. 13) is near zero, while the shape factor for sensing values corresponding to two objects (e.g., FIG. 14) is significantly above zero.

Thus, by analyzing the shape factor the number of the objects in the sensing region can be determined. As one example of how the shape factor may be analyzed, it may be compared to one or more threshold values to determine if the shape factor is above or below certain thresholds. In the example of FIGS. 13 and 14, a threshold value or approximately 20 may be used to determine the number of objects in the sensing region.

Thus, a sensor device is provided that comprises an array of capacitive sensing electrodes and a processing system coupled to the electrodes. The capacitive sensing electrodes are configured to generate sensing signals that are indicative of objects in a sensing region. The processing system is configured to receive sensing signals from the capacitive sensing electrodes and generate a plurality of sensing values. The processing system is further configured to calculate a sensing profile from the sensing values, calculate a profile span from the sensing values, and determine a shape factor from the sensing profile and the profile span. Finally, the processing system is configured to determine a number of objects in the sensing region from the determined shape factor. Thus, the sensor device facilitates the determination of the number of objects in the sensing region, and may thus be used to facilitate different user interface actions in response to different numbers of objects.

The embodiments and examples set forth herein were presented in order to best explain the present invention and its particular application and to thereby enable those skilled in the art to make and use the invention. However, those skilled in the art will recognize that the foregoing description and examples have been presented for the purposes of illustration and example only. The description as set forth is not intended to be exhaustive or to limit the invention to the precise form disclosed.

What is claimed is:

1. A sensor device comprising:
a first array of capacitive sensing electrodes, each of the first array of capacitive sensing electrodes configured to generate a sensing signal indicative of objects in a sensing region; and
a processing system coupled to the first array of capacitive sensing electrodes, the processing system configured to:
receive sensing signals from the first array of capacitive sensing electrodes and generate sensing values from the sensing signals;
calculate a sensing profile from the sensing values;
calculate a profile span from the sensing values;
determine a shape factor from the sensing profile and the profile span; and
determine a number of objects in the sensing region from the shape factor.

2. The sensor device of claim 1 wherein the processor is configured to determine the number of objects in the sensing region from the shape factor by determining if one object or two objects are in the sensing region.

3. The sensor device of claim 1 wherein the processor is configured to generate sensing values from the sensing signals by subtracting baseline sensing values determined when an object is not in the sensing region.

4. The sensor device of claim 1 wherein the processor is configured to calculate the sensing profile from the sensing values by calculating difference values for sensing values corresponding to adjacent sensing electrodes and summing the difference values.

5. The sensor device of claim 1 wherein the processor is configured to calculate the sensing profile from sensing signals received when at least one object is in the sensing region.

6. The sensor device of claim 1 wherein the processor is configured to calculate the profile span by determining a difference between a maximum sensing value and a minimum sensing value from the second set of the sensing values.

7. The sensor device of claim 1 wherein the processor is configured to determine the shape factor from the baseline profile, the sensing profile, and the profile span by:
comparing the sensing profile to twice the profile span.

8. The sensor device of claim 1 wherein the processor is configured to determine the number of objects in the sensing region from the shape factor by:
comparing the shape factor to a threshold.

9. The sensor device of claim 1 wherein the processor is configured to determine the number of objects in the sensing region from the shape factor by:
indicating a single object if the shape factor is approximately zero and by indicating two objects if the shape factor is beyond twice the span.

10. A sensor device comprising:
a first array of capacitive sensing electrodes, each of the first array of capacitive sensing electrodes configured to generate a sensing signal indicative of objects in a sensing region; and
a processing system coupled to the first array of capacitive sensing electrodes, the processing system configured to:
receive sensing signals from the first array of capacitive sensing electrodes corresponding to one or more objects being in the sensing region;
generate sensing values from the sensing signals, wherein the sensing values are generated in part by determining differences from sensing signals received from the first array of capacitive sensing electrodes when an object was not in the sensing region;
determine a sensing profile from the sensing values, wherein the sensing profile is determined by calculating difference values for sensing values corresponding to adjacent sensing electrodes and summing the difference values;
calculate a profile span from the second set of sensing values by determining a difference between a maximum sensing value and a minimum sensing value from the second set of the sensing values;
determine a shape factor from the sensing profile and the profile span; and
indicate a single object if the shape factor is approximately zero and by indicate two objects if the shape factor is beyond a threshold.

11. A method of determining a number of objects in a sensing region of a sensor with a first array of capacitive sensing electrodes, the method comprising:
receiving sensing signals from the first array of capacitive sensing electrodes and generating sensing values from the sensing signals;
calculating a sensing profile from the sensing values;
calculating a profile span from the sensing values;
determining a shape factor from the sensing profile, and the profile span; and
determining a number of objects in the sensing region from the shape factor.

12. The method of claim 11 wherein the step of determining the number of objects in the sensing region from the shape factor comprises determining if one object or two objects are in the sensing region.

13. The method of claim 11 wherein the step of calculating the sensing profile from the sensing values comprises calculating difference values for sensing values corresponding to adjacent capacitive sensing electrodes and summing the difference values.

14. The method of claim 11 wherein the step of calculating the sensing profile from the sensing values comprises calculating the sensing profile from sensing signals received when at least one object is in the sensing region.

15. The method of claim 11 wherein the step of calculating the profile span from the sensing values comprises determining a difference between a maximum sensing value and a minimum sensing value from the sensing values.

16. The method of claim 11 wherein the step of determining the shape factor from the sensing profile and the profile span comprises comparing the sensing profile to twice the profile span.

17. The method of claim 11 wherein the step of determining the number of objects in the sensing region from the shape factor comprises comparing the shape factor to a threshold.

18. The method of claim 11 wherein the step of determining the number of objects in the sensing region from the shape factor comprises indicating a single object if the shape factor is approximately zero and indicating two objects if the shape factor is beyond twice the span.

19. A program product, comprising:
A) a proximity sensor program, the proximity sensor program configured to:
receive sensing signals from a first array of capacitive sensing electrodes and generate sensing values from the sensing signals;
calculate a sensing profile from the sensing values;
calculate a profile span from the sensing values;
determine a shape factor from the sensing profile and the profile span; and
determine a number of at least two objects in the sensing region from the shape factor; and
B) computer-readable media bearing the proximity sensor program.

20. A sensor device comprising:
a first array of sensing electrodes, each of the first array of sensing electrodes configured to generate a sensing signal indicative of objects in a sensing region; and
a processing system coupled to the first array sensing electrodes, the processing system configured to:
receive sensing signals from the first array of sensing electrodes and generate sensing values from the sensing signals;
calculate a sensing profile from the sensing values;
calculate a profile span from the sensing values;
determine a shape factor from the sensing profile and the profile span; and
determine a number of objects in the sensing region from the shape factor.
